(19) United States
(12) Patent Application Publication
(10) Pub. No.: US 2026/0314346 A1
(43) Pub. Date: Oct. 8, 2026

(54) PROCESS FOR DOUBLE LAYER TRANSFER

(71) Applicant: Soitec, BERNIN (FR)

(72) Inventor: Christophe Figuet, BERNIN (FR)

(21) Appl. No.: 19/478,991

(22) PCT Filed: May 17, 2024
(86) PCT No.: PCT/EP2024/063679

§ 371 Date: Oct. 27, 2025

(30) Foreign Application Priority Data
May 22, 2023 (FR) FR2305015

(51) Int. Cl. H10P 90/00

(52) U.S. Cl. CPC H10P 90/21; H10P 90/1916

(57) ABSTRACT

A method for double transfer of a layer includes: providing a heterostructure including a growth substrate, an interlayer of two-dimensional material and an epitaxial layer of semiconductor material; providing a rigid substrate including a weakened plane; producing a first assembly by bonding the rigid substrate to the heterostructure, the first side and the epitaxial layer being at the bonding interface; splitting the first assembly at the interlayer of two-dimensional material to obtain a second assembly resulting from transfer of the epitaxial layer from the heterostructure to the rigid substrate; producing a third assembly by bonding the second assembly with a target substrate, the epitaxial layer being at the bonding interface; and splitting the third assembly along the weakened plane of the rigid substrate.

### CROSS-REFERENCE TO RELATED APPLICATIONS

This application is a national phase entry under 35 U.S.C. § 371 of International Patent Application PCT/EP 2024/063679, filed May 17, 2024, designating the United States of America and published as International Patent Publication WO 2024/240636 A1 on Nov. 28, 2024, which claims the benefit under Article 8 of the Patent Cooperation Treaty of French Patent Application Serial No. FR 2305015, filed May 22, 2023.

### TECHNICAL FIELD

Methods for fabricating a stacked structure comprising a thin layer of semiconductor material adhering to a target substrate. The disclosure relates more particularly to methods that use a technique for transferring a layer based on 2D material.

### BACKGROUND

Remote epitaxy is a method for producing thin layers of semiconductor material, disclosed, for example, in Kim, H., Chang, C. S., Lee, S. et al., Remote epitaxy. Nat. Rev. Methods Primers 2, 40 (2022), https://doi.org/10.1038/s43586-022-00122-w.

This method involves placing, between a growth substrate and the semiconductor layer being grown by epitaxy, a layer of two-dimensional material (2D material, also called Van der Waals material), which has strong atomic bonds in the plane but weak Van der Waals interaction outside of the plane. This layer of 2D material behaves like a pseudo-transparent substrate: the crystalline structure of the epitaxial layer copies that of the growth substrate, as if the intermediate layer of 2D material did not exist. The advantage is that the epitaxial layer can be easily separated from the growth substrate owing to the absence of covalent bonds between the growth substrate and the epitaxial layer. The substrate, which may be expensive, may thus be reused.

As stated in the above article, the separation at the layer of 2D material involves first depositing on the epitaxial layer a stressor layer made of nickel then placing a thermal release adhesive film on the stressor layer. The stack made up of the adhesive film, the layer of nickel and the epitaxial layer may then be exfoliated from the growth substrate following detachment induced at the layer of 2D material by supplying mechanical energy.

As reported in the above article, this sequence of steps has a number of disadvantages.

First of all, the deposition of a layer of nickel gives rise to contamination both at the epitaxial layer, which is in contact with the layer of nickel, and at the growth substrate, which is loaded in a metal deposition apparatus. Additional protective layers may be deposited to limit contact and interaction and then later removed. Thus, several additional steps must be carried out to solve this problem of contamination, which is detrimental to the cost of the method, not to mention the impact of these additional steps on the quality of the epitaxial layer and its exfoliation.

Then, the deposition of the layer of nickel is generally carried out by sputtering. The epitaxial layer is therefore bombarded with ions, which impairs its quality over a thickness of a few nanometers, or even several dozen nanometers. As a result, in particular when the epitaxial layer has a small thickness and damaging a few dozen nanometers must therefore be avoided, deposition of a protective layer may be necessary to protect the epitaxial layer. Again, additional steps must be implemented, which has an impact both on the cost and on the yield of the method.

Moreover, stress is applied to induce detachment at the layer of 2D material. This stress must be uniform throughout the detachment process and from one end of the interface consisting of the layer of 2D material to the other, since slight variations can result in a crack in the epitaxial layer if this stress exceeds the mechanical fatigue limit of the epitaxial layer. The layer of nickel helps, owing to its thickness, to prevent such cracking during detachment, but it is not a universal solution.

Lastly, during this detachment, the epitaxial layer is subject to bending, which can cause fissures therein. Subsequent handling of this layer with a view to transferring it onto a target substrate is moreover carried out using the adhesive film, which is flexible. This also gives rise to a risk of fissures or cracks forming in the epitaxial layer.

### BRIEF SUMMARY

The present disclosure proposes a remote epitaxy technique that can make it possible to overcome the abovementioned drawbacks and thus preserve the integrity of the epitaxial layer.

To this end, a method for double transfer of a layer is disclosed, comprising the following steps:
supplying a heterostructure comprising a growth substrate, an interlayer of two-dimensional material on the growth substrate and at least one epitaxial layer of semiconductor material formed on the interlayer;
supplying a rigid substrate comprising a weakened plane formed by ion implantation through a first face of the rigid substrate, the weakened plane separating a thin layer from a bulk part of the rigid substrate;
producing a first assembly by bonding the rigid substrate with the heterostructure, the first face of the rigid substrate and the at least one epitaxial layer of the heterostructure being at the bonding interface of the rigid substrate and the heterostructure;
separating the first assembly at the interlayer of two-dimensional material in such a way as to obtain a second assembly resulting from the transfer of the at least one epitaxial layer from the heterostructure to the rigid substrate;
producing a third assembly by bonding the second assembly with a target substrate, the at least one epitaxial layer being at the bonding interface between the second assembly and the target substrate;
separating the third assembly along the weakened plane of the rigid substrate in such a way as to obtain a fourth assembly resulting from the transfer of the at least one epitaxial layer and of the thin layer of the third assembly to the target substrate.

Certain preferred but non-limiting aspects of this method are as follows:
the bonding of the rigid substrate with the heterostructure to produce the first assembly is a surface-activated bonding;
the bonding of the rigid substrate with the heterostructure to produce the first assembly is an atomic diffusion bonding;
the separation of the first assembly at the interlayer of two-dimensional material comprises supplying mechanical and/or thermal energy;
thermal energy is supplied at a temperature lower than a temperature at which the rigid substrate separates at the weakened plane;
the growth substrate and the rigid substrate have thermal expansion coefficients that differ by at least 0.3 ppm/K;
the second assembly is subjected to one or more technological steps of fabrication of semiconductor structures, each performed at a temperature lower than a temperature at which the rigid substrate separates at the weakened plane;
it further comprises the removal of the thin layer from the fourth assembly;
it further comprises, after the removal of the thin layer, epitaxy of the semiconductor material on the at least one epitaxial layer;
the at least one epitaxial layer of semiconductor material comprises a layer of polar material, for example, a layer of GaN;
the target substrate is a polycrystalline SiC substrate, a polycrystalline AIN substrate, a Si substrate with high electrical resistivity or a substrate bearing a layer of semi-insulating SiC;
the growth substrate is a silicon substrate of orientation (111).

### BRIEF DESCRIPTION OF THE DRAWINGS

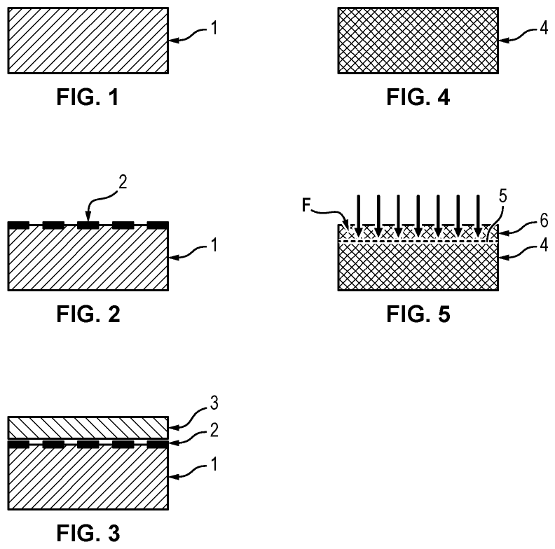

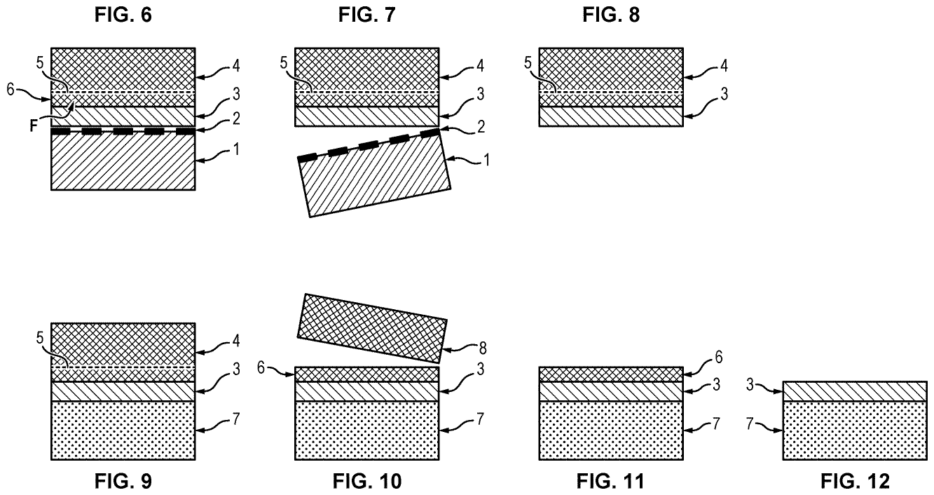

Other aspects, aims, advantages and features of the disclosure will become more clearly apparent on reading the following detailed description of preferred embodiments of the disclosure, given by way of non-limiting examples and set out with reference to the accompanying drawings, FIGS. 1 to 12 of which depict a possible embodiment of a method according to the disclosure.

### DETAILED DESCRIPTION

The present disclosure relates to a method for double transfer of a layer, which combines the transfer of a semiconductor layer from a growth substrate to a rigid substrate using the transfer technique based on two-dimensional (2D) material, then the transfer of the semiconductor layer from the rigid substrate to a target substrate using the Smart Cut™ transfer technique.

In the context of this double transfer, the use of the rigid substrate makes it possible to perform the first transfer by detachment at the two-dimensional material without giving rise to fissures in the semiconductor layer and without requiring a metal stressor layer. This use also makes it possible to handle the semiconductor layer so as to transfer it onto the target substrate without fissures or cracks forming in the semiconductor layer.

The method according to the disclosure comprises a step of supplying a heterostructure comprising a growth substrate, an interlayer of two-dimensional material on the growth substrate and one (or more) epitaxial layer(s) of semiconductor material formed on the interlayer.

This supply may result from the fabrication of the heterostructure in the context of a possible embodiment of the method according to the disclosure.

With reference to FIG. 1, in this embodiment, the method comprises supplying the growth substrate 1, which is, for example, a Si substrate (of orientation (111) in particular), a sapphire substrate or a GaN substrate.

With reference to FIG. 2, in this embodiment the method then comprises the formation of the interlayer of two-dimensional material 2 on the growth substrate 1. This formation may be carried out after planarization of the surface of the growth substrate, for example, by means of mechanical-chemical polishing. The surface of the growth substrate may also be cleaned. This formation may comprise the deposition of the two-dimensional material 2 on the growth substrate 1. Purely by way of example, this deposition may be performed by means of MBE (Molecular Beam Epitaxy), CVD (Chemical Vapor Deposition) or ALD (Atomic Layer Deposition).

The two-dimensional material may be hexagonal boron nitride, h-BN, graphene or more generally any Van der Waals 2D material making it possible to perform remote epitaxy. The layer of two-dimensional material is thus made up of monoatomic sheets (single-atom layers) having weak interaction between them and limited in number to allow the remote epitaxy of the layer of semiconductor material. In a possible embodiment, the number of sheets may be less than three.

With reference to FIG. 3, in this embodiment, the method further comprises the growth of the epitaxial layer of semiconductor material 3 on the interlayer of two-dimensional material 2. This growth generally takes place in two main steps: nucleation on the layer of two-dimensional material and standard growth of the epitaxial layer of semiconductor material. These two steps may be carried out at different growth temperatures, the nucleation being carried out at a temperature lower than the standard growth.

The thickness of the epitaxial layer 3 is typically between 100 nm and a few microns, preferably between 500 nm and 2 microns in particular in the case of an epitaxial layer of GaN. The epitaxial layer of semiconductor material may be a layer of polar material, for example, a layer of GaN, of AlN or of SiC. In the case of a layer of GaN or of AlN, it has, by virtue of its polarity, the characteristic of having, on one face, a surface consisting mainly of nitrogen atoms (N surface) and, on the other face, a surface consisting mainly of gallium atoms (Ga surface) or aluminum atoms (Al surface). In the case at hand, the Ga surface or Al surface is at the interface with the layer of two-dimensional material 2 while the N surface forms a free surface. The same applies with a layer of SiC, for which there is a Si surface at the interface with the layer of two-dimensional material 2 while a C surface forms a free surface.

In a possible embodiment, the method comprises the growth of several epitaxial layers forming a stack of crystalline layers. Below, the example of a single epitaxial layer will be discussed, it being understood that the disclosure is not limited to this scenario.

The method according to the disclosure further comprises a step of supplying a rigid substrate that comprises a weakened plane formed by ion implantation through a first face of the rigid substrate. This weakened plane separates a thin layer from a bulk part of the rigid substrate.

This supply may result from the preparation of the rigid substrate in the context of a possible embodiment of the method according to the disclosure.

With reference to FIG. 4, in this embodiment, the method comprises supplying the rigid substrate 4, preferably an inexpensive substrate, for example, a silicon substrate, in particular a silicon substrate of crystalline orientation (111).

Then, with reference to FIG. 5, in this embodiment the method comprises the implantation of ion species through a face F of the rigid substrate 4 in such a way as to form therein a weakened plane 5 separating a thin layer 6 from a bulk part of the rigid substrate. The implanted species typically comprise hydrogen and/or helium. A person skilled in the art will be able to define the required implantation dose and energy.

Once the heterostructure and the implanted rigid substrate have been supplied, the method according to the disclosure comprises, with reference to FIG. 6, producing a first assembly by bonding the rigid substrate 4 with the heterostructure. This bonding is carried out such that the first face of the rigid substrate 4 and the epitaxial layer 3 of the heterostructure are at the bonding interface of the rigid substrate and the heterostructure.

The bonding is carried out in such a way as to obtain bonding energy at the bonding interface of the rigid substrate and the heterostructure that is greater than the bonding energy of the Van der Waals interface between the two-dimensional material and the epitaxial layer.

The bonding may be carried out at ambient temperature. In a possible embodiment, it is carried out under reduced pressure. A heat treatment for strengthening the bonding may also be carried out, at a temperature lower than that of a heat treatment that would cause the rigid substrate to separate at the weakened plane.

In a preferred embodiment making it possible to obtain a very strong bonding interface, the-bonding of the rigid substrate with the heterostructure to produce the first assembly is SAB (Surface-Activated Bonding), ADP (Atomic Diffusion Bonding) or hydrophilic bonding accompanied by annealing to strengthen the bonding.

With reference to FIG. 7, the method then comprises separating the first assembly at the interlayer of two-dimensional material 2 in such a way as to obtain, as shown in FIG. 8, a second assembly resulting from the transfer of the epitaxial layer 3 from the heterostructure to the rigid substrate 4.

This separation of the epitaxial layer 3 from the growth substrate 1 may be carried out by supplying mechanical and/or thermal energy at the layer of two-dimensional material 2. When carried out by supplying thermal energy in conjunction, or not in conjunction, with supplying mechanical energy, the separation takes advantage of stress induced during heating or subsequent cooling owing to a difference in thermal expansion coefficient between the growth substrate 1 and the rigid substrate 4. To this end, the growth substrate and the rigid substrate preferably have thermal expansion coefficients that differ by at least 0.3 ppm/K. Thermal energy is supplied at a temperature lower than that of a heat treatment that would cause the rigid substrate to separate at the weakened plane. As an example, it is possible to use a growth substrate 1 made of GaN (having a thermal expansion coefficient of 5.6 ppm/K) and a rigid substrate 4 made of Si (having a thermal expansion coefficient of 2.6 ppm/K), produce the first assembly by bonding at ambient temperature and then apply heating so as to induce compressive stress in the GaN substrate.

Note that it is advantageous to carry out the implantation in the rigid substrate before the bonding and the detachment shown in FIGS. 6 and 7. This makes it possible to preserve the integrity of the epitaxial layer 3 compared to a solution involving carrying out the implantation in the rigid substrate after the detachment of FIG. 7 in the epitaxial layer 3 and through the epitaxial layer 3.

In a possible embodiment, after the detachment of FIG. 7, the second assembly shown in FIG. 8, and more specifically the epitaxial layer 3 transferred onto the rigid substrate 4, is subjected to one or more technological steps of fabrication of semiconductor structures. These steps may, in particular, involve cleaning, polishing, deposition or etching. Each of these steps is performed at a temperature lower than that of a heat treatment that would cause the rigid substrate to separate at the weakened plane.

After obtaining the second assembly shown in FIG. 8, the method comprises, with reference to FIG. 9, producing a third assembly by bonding the second assembly with a target substrate 7, the epitaxial layer 3 being at the bonding interface between the second assembly and the target substrate. This bonding may be hydrophilic bonding, possibly accompanied by annealing to strengthen the bonding.

Next, with reference to FIG. 10, the method comprises separating the third assembly along the weakened plane 5 of the rigid substrate 4. As shown in FIG. 11, this separation leads to a fourth assembly resulting from the transfer of the epitaxial layer 3 and of the thin layer 6 of the third assembly to the target substrate 7. This separation is typically obtained by applying a separation heat treatment at a temperature, which may be between 200° C. and 600° C. for silicon.

Note that the method according to the disclosure makes it possible to recycle the growth substrate and the rigid substrate so as to reuse them in an identical method or for another purpose.

As shown in FIG. 12, the method may then comprise the removal of the thin layer 6 from the fourth assembly, for example, by etching, in such a way as to keep only the epitaxial layer 3 on the target substrate 7.

After removal of the thin layer 6, the method may also comprise restarting epitaxy on the epitaxial layer. Note that when the epitaxial layer is a layer of polar material, the double transfer performed by the disclosure advantageously makes it possible to expose the surface (for example, Ga, Al or Si surface) of the epitaxial layer, allowing epitaxy of the semiconductor material on the epitaxial layer to be thus restarted.

The target substrate 7 may be a polycrystalline SiC substrate or a polycrystalline AIN substrate. Alternatively, the target substrate 7 may be a Si substrate with high electrical resistivity. As another alternative, the target substrate may be a substrate bearing a layer of semi-insulating SiC, for example, a Si substrate, optionally with high electrical resistivity, bearing such a layer of semi-insulating SiC. The epitaxial layer 3 transferred onto a target substrate in accordance with these examples may be a layer of GaN. “Semi-insulating material” means a material typically having an electrical resistivity higher than or equal to 105 Ω/cm. “Material having a high electrical resistivity” means a material typically having an electrical resistivity higher than or equal to 100 Ω/cm.

1. A method for double transfer of a layer, comprising
providing a heterostructure comprising a growth substrate, an interlayer of two-dimensional material on the growth substrate and at least one epitaxial layer of semiconductor material formed on the interlayer;
providing a rigid substrate comprising a weakened plane formed by ion implantation through a first face of the rigid substrate, the weakened plane separating a thin layer-(from a bulk part of the rigid substrate;
producing a first assembly by bonding the rigid substrate with the heterostructure, the first face of the rigid substrate and the at least one epitaxial layer of the heterostructure being at a bonding interface of the rigid substrate and the heterostructure;
separating the first assembly at the interlayer of two-dimensional material to obtain a second assembly resulting from the transfer of the at least one epitaxial layer from the heterostructure to the rigid substrate;
producing a third assembly by bonding the second assembly with a target substrate, the at least one epitaxial layer being at the bonding interface between the second assembly and the target substrate; and
separating the third assembly along the weakened plane of the rigid substrate to obtain a fourth assembly resulting from the transfer of the at least one epitaxial layer and of the thin layer of the third assembly to the target substrate.

2. The method of claim 1, wherein the bonding of the rigid substrate with the heterostructure to produce the first assembly comprises surface-activated bonding.

3. The method of claim 1, wherein the bonding of the rigid substrate with the heterostructure to produce the first assembly comprises atomic diffusion bonding.

4. The method of claim 1, wherein the separation of the first assembly at the interlayer of two-dimensional material comprises applying mechanical and/or thermal energy at the interlayer.

5. The method of claim 4, wherein thermal energy is applied at a temperature lower than a temperature at which the rigid substrate separates at the weakened plane.

6. The method of claim 5, wherein the growth substrate and the rigid substrate have thermal expansion coefficients that differ by at least 0.3 ppm/K.

7. The method of claim 1, further comprising forming at least one process for fabricating semiconductor structures, the at least one process performed at a temperature lower than a temperature at which the rigid substrate separates at the weakened plane.

8. The method of claim 1, further comprising removing the thin layer from the fourth assembly.

9. The method of claim 8, further comprising, after the removing of the thin layer, conducting epitaxial growth of the semiconductor material on the at least one epitaxial layer.

10. The method of claim 1, wherein the at least one epitaxial layer of semiconductor material comprises a layer of polar material.

11. The method of claim 1, wherein the target substrate is a polycrystalline SiC substrate, a polycrystalline AIN substrate, a Si substrate with high electrical resistivity or a substrate bearing a layer of semi-insulating SiC.

12. The method of claim 1, wherein the growth substrate is a silicon substrate of orientation (111).

13. The method of claim 2, wherein the separation of the first assembly at the interlayer of two-dimensional material comprises applying mechanical and/or thermal energy at the interlayer.

14. The method of claim 3, wherein the separation of the first assembly at the interlayer of two-dimensional material comprises applying mechanical and/or thermal energy at the interlayer.

15. The method of claim 6, further comprising forming at least one process for fabricating semiconductor structures, the at least one process performed at a temperature lower than a temperature at which the rigid substrate separates at the weakened plane.

16. The method of claim 15, further comprising removing the thin layer from the fourth assembly.

17. The method of claim 16, further comprising, after the removing the thin layer, conducting epitaxial growth of the semiconductor material on the at least one epitaxial layer.

18. The method of claim 17, wherein the at least one epitaxial layer of semiconductor material comprises a layer of polar material.

19. The method of claim 18, wherein the target substrate is a polycrystalline SiC substrate, a polycrystalline AIN substrate, a Si substrate with high electrical resistivity or a substrate bearing a layer of semi-insulating SiC.

20. The method of claim 19, wherein the growth substrate is a silicon substrate of orientation (111).
